(19) United States
(12) Patent Application Publication
(10) Pub. No.: US 2023/0268254 A1
(43) Pub. Date: Aug. 24, 2023

(54) ELECTRONIC DEVICE WITH FRAME COMPONENT

(71) Applicant: Advanced Semiconductor Engineering, Inc., Kaohsiung (TW)

(72) Inventor: Hui-Chen HSU, Kaohsiung (TW)

(73) Assignee: Advanced Semiconductor Engineering, Inc., Kaohsiung (TW)

(21) Appl. No.: 17/676,092

(22) Filed: Feb. 18, 2022

(51) Int. Cl. H01L 23/495

(52) U.S. Cl. CPC H01L 23/49548; H01L 23/49503

(57) ABSTRACT

An electronic device is provided. The electronic device includes a circuit pattern layer. The circuit pattern layer includes a first surface, a second surface recessed with respect to the first surface; and a third surface recessed with respect to the first surface and adjacent to and spaced apart from the second surface. The second surface and the third surface are mis-aligned with each other.

### BACKGROUND

### 1. Field of the Disclosure

The instant disclosure relates to, amongst other things, an electronic device with a frame component. The frame component includes at least one die paddle and a plurality of leads.

### 2. Description of Related Art

QFN (Quad Flat No-lead)/DFN (Dual Flat No-lead) is a near CSP (Chip Size Package) encapsulated package using a lead frame. The lead frame includes a die paddle and a plurality of leads The QFN/DFN package is a leadless surface mount package in which the lead frame is located at and exposed from the bottom of the package. Thus, a very compact size of the package and a minimum foot print area of PCB were obtained. However, the lower surface of the lead and the lower surface of the doe paddle exposed from the bottom of the package are substantially flat, and thus solder connections cannot be fixedly attached to the lower surface of the lead and the lower surface of the die paddle. When the QFN/DFN package is electrically connected to the printed circuit board through the solder connections and a Board Level Reliability Test is performed, a crack issue may occur between the solder connection and the lead frame.

### SUMMARY

According to one example embodiment of the instant disclosure, an electronic device includes a frame component. The frame component includes a first surface, a second surface recessed with respect to the first surface; and a third surface recessed with respect to the first surface and adjacent to and spaced apart from the second surface. The second surface and the third surface are mis-aligned with each other.

According to another example embodiment of the instant disclosure, an electronic device includes a frame component. The frame component includes a first surface, and a first recess formed on the first surface. The first recess is configured to block a transmission of a first shear force applied on the first surface of the frame component.

According to another example embodiment of the instant disclosure, an electronic device includes a lead frame and a component. The lead frame has a first surface with a plurality of recessed portions, and the component is attached to the first surface of the lead frame. The first surface and the recessed portions of the lead frame are configured to hold the component when performing at least one stress test on the electronic device.

In order to further understanding of the instant disclosure, the following embodiments are provided along with illustrations to facilitate appreciation of the instant disclosure; however, the appended drawings are merely provided for reference and illustration, and do not limit the scope of the instant disclosure.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1A is a schematic bottom view of a lead frame in accordance with an embodiment of the instant disclosure.

FIG. 1B illustrates an enlarged view of portion Ain FIG. 1A.

FIG. 1C illustrates an enlarged view of portion B in FIG. 1A.

FIG. 1D illustrates another enlarged view of portion A in FIG. 1A.

FIG. 1E illustrates another enlarged view of portion B in FIG. 1A.

FIG. 2A is a schematic top view of a lead frame in accordance with an embodiment of the instant disclosure.

FIG. 2B illustrates an enlarged view of portion C in FIG. 2A.

FIG. 2C illustrates an enlarged view of portion D in FIG. 2A.

FIG. 2D illustrates another enlarged view of portion C in FIG. 2A.

FIG. 2E illustrates another enlarged view of portion D in FIG. 2A.

FIG. 2F illustrates a schematic cross-sectional view along line I-I′ in FIG. 2A.

FIG. 3A is a schematic cross-sectional view of a package structure in accordance with an embodiment of the instant disclosure.

FIG. 3B is a schematic bottom view of a package structure in accordance with an embodiment of the instant disclosure.

FIG. 3C illustrates an enlarged view of portion E in FIG. 3B.

FIG. 4 is a schematic cross-sectional view of an electronic device in accordance with an embodiment of the instant disclosure.

FIG. 5A is a schematic view of a die paddle of a lead frame in accordance with an embodiment of the instant disclosure.

FIG. 5B is a schematic view of a die paddle of a lead frame in accordance with an embodiment of the instant disclosure.

FIG. 5C is a schematic view of a die paddle of a lead frame in accordance with an embodiment of the instant disclosure.

FIG. 5D is a schematic view of a die paddle of a lead frame in accordance with an embodiment of the instant disclosure.

FIG. 5E is a schematic view of a die paddle of a lead frame in accordance with an embodiment of the instant disclosure.

FIG. 6A is a schematic view of a lead of a lead frame in accordance with an embodiment of the instant disclosure.

FIG. 6B is a schematic view of a lead of a lead frame in accordance with an embodiment of the instant disclosure.

FIG. 6C is a schematic view of a lead of a lead frame in accordance with an embodiment of the instant disclosure.

FIG. 6D is a schematic view of a lead of a lead frame in accordance with an embodiment of the instant disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides for many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features are formed or disposed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein, spatially relative terms, such as “beneath,” “below,” “above,” “over,” “on,” “upper,” “lower,” “left,” “right,” “vertical,” “horizontal,” “side” and the like, may be used herein for ease of description to describe one element or feature's relationship to another element(s) or feature(s) as illustrated in the Figures. The spatially relative terms are intended to encompass different orientations of the device in use or operation in addition to the orientation depicted in the Figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

Present disclosure provides an electronic device with a lead frame, which includes a plurality recessed portions formed on an upper surface and/or a lower surface of the lead frame. These recessed portions are configured to eliminate a shear stress on the upper surface and/or the lower surface of the lead frame. That is, an element which is attached to the lead frame is firmly held by the recessed portions of the lead frame. There is no crack issue between the element and the lead frame. In some embodiments of the present disclosure, the lead frame is a circuit pattern layer of the electronic device.

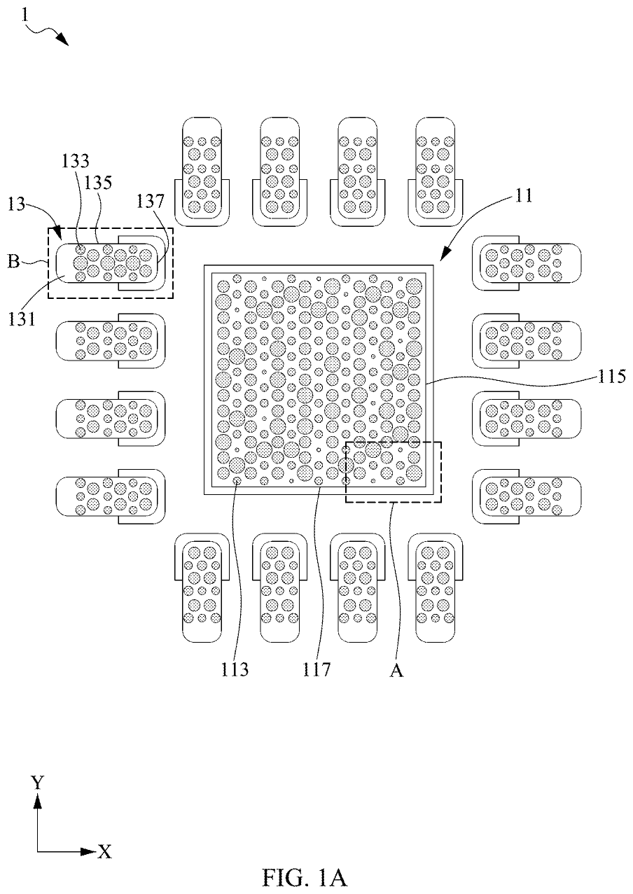

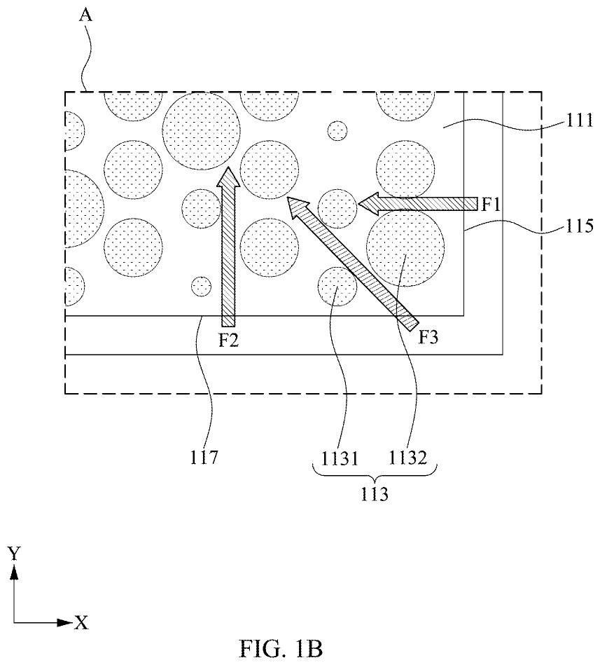

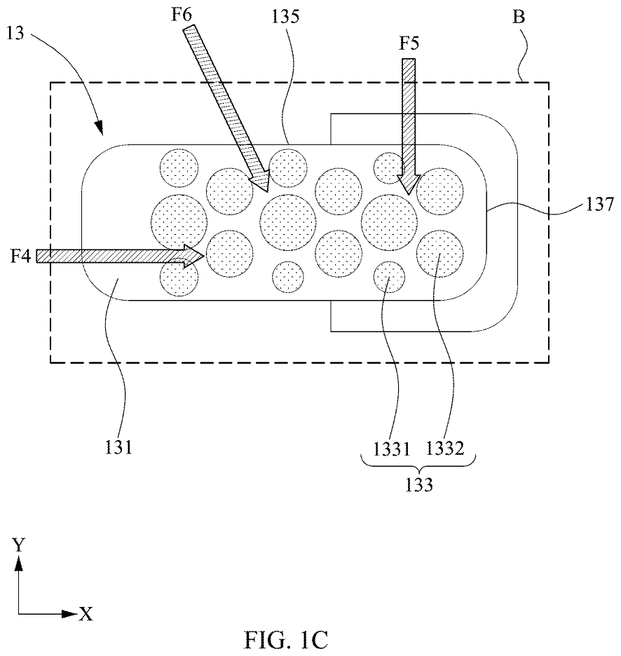

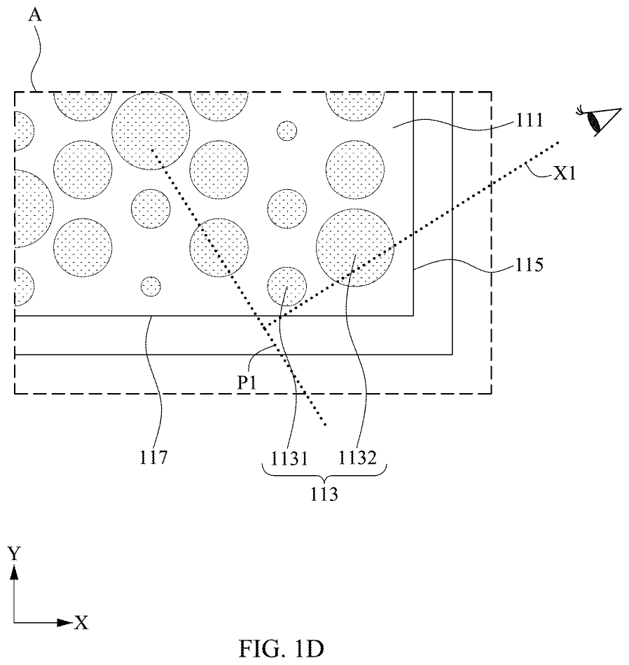

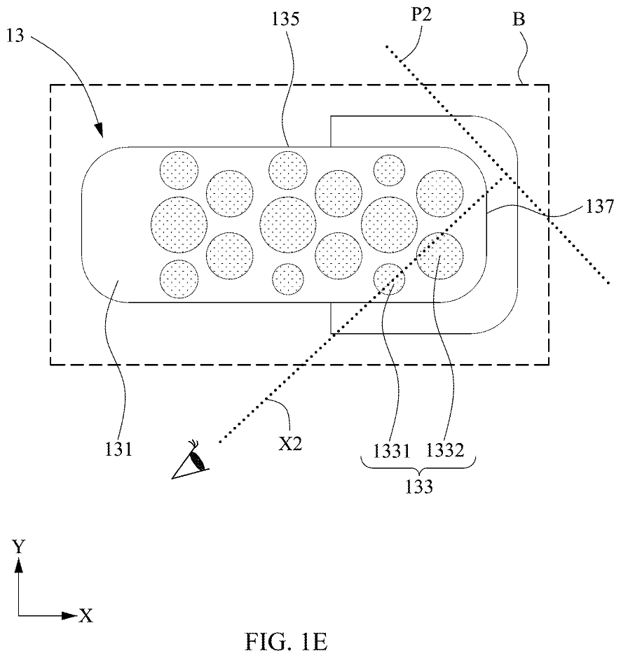

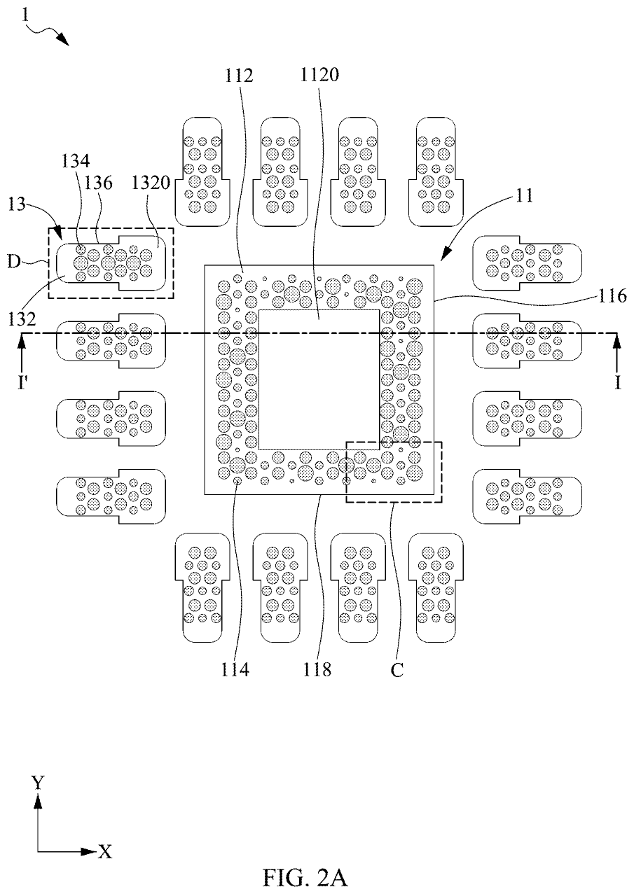

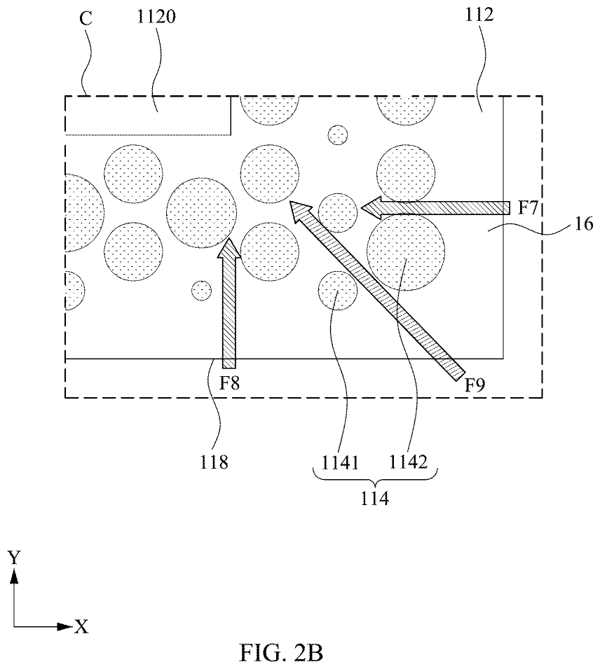

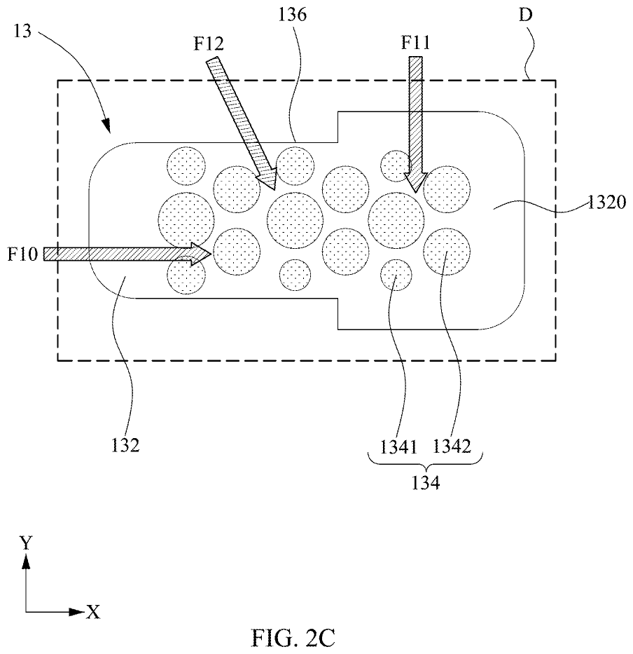

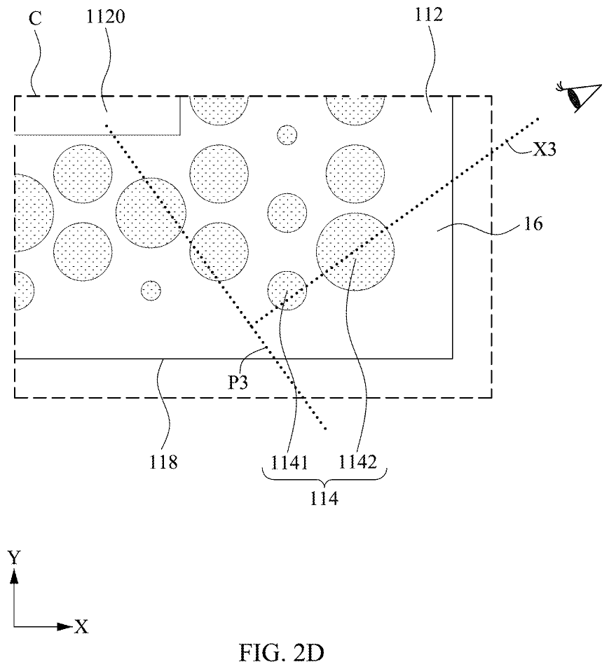

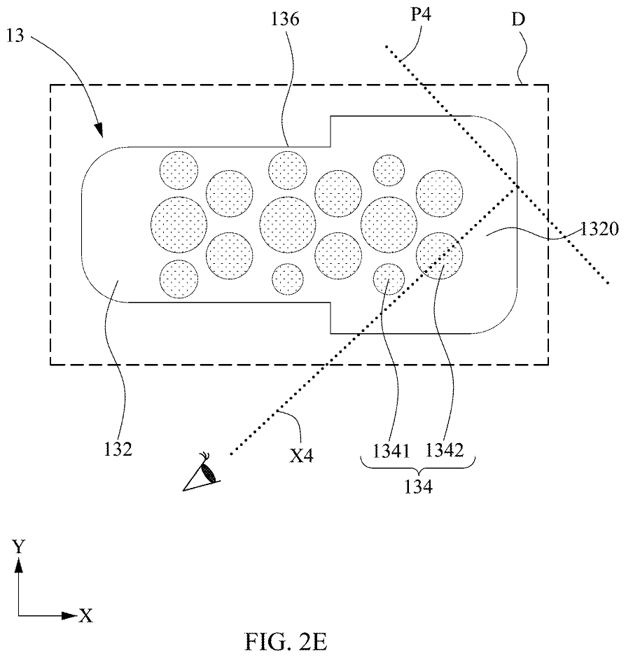

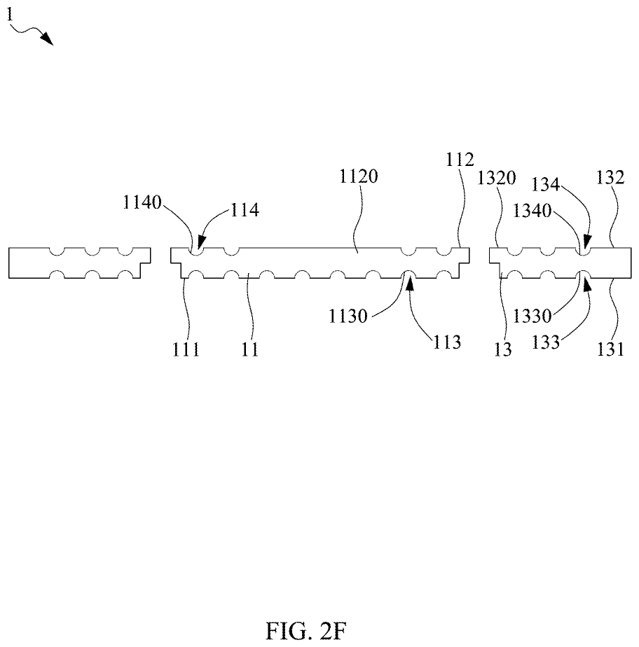

FIG. 1A is a schematic bottom view of a lead frame 1 in accordance with an embodiment of the instant disclosure. FIG. 2A is a schematic top view of the lead frame 1 in accordance with an embodiment of the instant disclosure. Referring to FIG. 1A and FIG. 2A, the lead frame 1 includes a die paddle 11 and a plurality of leads 13 surrounding the die paddle 11. Further, the lead 13 is spaced apart from the die paddle 11.

As shown in FIG. 1A, the die paddle 11 includes a lower surface 111. Further, the lower surface 111 of the die paddle 11 has a plurality of recessed portions 113. In some embodiments of the recessed portion 113 are formed on the lower surface 111 of the die paddle 11 by a half-etching process. In some embodiments of the present disclosure, the recessed portions 113 include dimples. In some embodiments of the present disclosure, the recessed portions 113 are the same size. In some embodiments of the present disclosure, the sizes of the recessed portions 113 are not the same. Referring to FIG. 1A, the recessed portions 113 may be arranged to be spaced apart from each other and to be adjacent to each other. Further, the recessed portions 113 may be mis-aligned with each other on the lower surface 111 of the paddle portion 11. That is, the recessed portions 113 may at least partially overlaps each other when viewed from an X-direction on the lower surface 111, from a Y-direction on the lower surface 111 or from any other direction on the lower surface 111. The lower surface 111 of the die paddle 11 has a first side 115 and a second side 117 connected to the first side 115. A distance between the recessed portion 113 and the first side 115 of the lower surface 111 of the die paddle 11 is greater than zero, and a distance between the recessed portion 113 and the second side 117 of the lower surface of the die paddle 11 is greater than zero. That is, the recessed portion 113 is spaced apart from the first side 115 and the second side 117 of the lower surface 111 of the die paddle 11.

The recessed portions 113 of the lower surface 111 of the die paddle 11 are configured to eliminate a shear force applied on the lower surface 111 of the die paddle 11. The recessed portion 113 has a surface recessed with respect to the lower surface 111 of the die paddle 11. Thus, once the shear force applied and transmitted on the lower surface 111 of the die paddle 11 meets the recessed portion 113, the shear stress is eliminated. That is, the recessed portion 113 is a barricade to block a transmission of the shear stress on the lower surface 111 of the die paddle 11. Further, since the recessed portions 113 are mis-aligned with each other on the lower surface 111, the shear force applied on the lower surface 111 meets the recessed portion 113 and is blocked and eliminated by the recessed portion 113 whether the transmission of the shear stress is in the X-direction, in the Y-direction or in any other direction. That is, no matter which direction the shear stress comes from on the lower surface 111 of the die paddle 11, the shear stress is eliminated by the recessed portion 113. Given the above, no shear stress passes across the whole lower surface 111 of the paddle portion 11.

FIG. 1B illustrates an enlarged view of portion A in FIG. 1A. That is, a portion of the lower surface 111 of the die paddle 11 is shown in FIG. 1B. Referring to FIG. 1B, a plurality of the recessed portions 113 are formed on the lower surface 111 of the die paddle 11. The recessed portion 113 may be adjacent to the first side 115 or the second side 117 of the lower surface 111 of the die paddle 11 but spaced apart from the first side 115 or the second side 117 of the lower surface 111 of the die paddle 11. In some embodiments of the present disclosure, the recessed portion 113 is surrounded by the lower surface 111 of the die paddle 11. The recessed portions 113 are mis-aligned with each other. In some embodiments of the present disclosure, the recessed portion 113 includes a first recessed portion 1131 and a second recessed portion 1132. As shown in FIG. 1B, the first recessed portion 1131 and the second recessed portion 1132 may be arranged to be adjacent to each other and be spaced apart from each other. Further, the first recessed portion 1131 and the second recessed portion 1132 may be mis-aligned with each other. Thus, the first recessed portion 1131 and the second recessed portion 1132 may at least partially overlaps each other when viewed from an X-direction or when viewed from a Y-direction or when viewed form another direction.

As above mentioned, the recessed portions 113 are configured to eliminate a shear force applied on the lower surface 111 of the die paddle 11. The recessed portion 113 may block the transmission of the shear stress on the lower surface 111 of the die paddle 11. Referring to FIG. 1B, when a shear stress F 1 is applied on the lower surface 111 and transmitted along the X-direction, the shear stress Fl meets at least one recessed portion 113 and thus the shear stress Fl is blocked and eliminated by the recessed portion(s) 113. When a shear stress F2 is applied on the lower surface 111 and transmitted along the Y-direction, the shear stress F2 meets at least one recessed portion 113 and thus the shear stress F2 is blocked and eliminated by the recessed portion(s) 113. A shear stress F3 is applied on the lower surface 111 and transmitted along a direction, which is not the X-direction or the Y-direction, the shear stress F3 meets at least one recessed portion 113 and thus the shear stress F3 is blocked and eliminated by the recessed portion(s) 113. In some embodiments of the present disclosure, a shear force strength of the recessed portion 1131 is different from a shear force strength of the recessed portion 1132. Moreover, the different sizes of the recessed portions 113 are configured to reduce or release the different shear stress at different position.

As shown in FIG. 1A, the lead 13 includes a lower surface 131. Further, the lower surface 131 of the lead 13 has a plurality of recessed portions 133. In some embodiments of the recessed portion 133 are formed on the lower surface 131 of the lead 13 by a half-etching process. In some embodiments of the present disclosure, the recessed portions 133 include dimples. In some embodiments of the present disclosure, the recessed portions 133 are the same size. In some embodiments of the present disclosure, the sizes of the recessed portions 133 are not the same. Referring to FIG. 1A, the recessed portions 133 may be arranged to be spaced apart from each other and to be adjacent to each other. Further, the recessed portions 133 may be mis-aligned with each other on the lower surface 131 of the lead 13. That is, the recessed portions 133 may at least partially overlaps each other when viewed from an X-direction on the lower surface 131, from a Y-direction on the lower surface 131 or from any other direction on the lower surface 131. The lower surface 131 of the lead 13 has a first side 135 and a second side 137 connected to the first side 135. A distance between the recessed portion 133 and the first side 135 of the lead 13 is greater than zero, and a distance between the recessed portion 133 and the second side 137 of the lead 13 is greater than zero. That is, the recessed portion 133 is spaced apart from the first side 135 and the second side 137 of the lower surface 131 of the lead 13.

The recessed portions 133 of the lower surface 131 of the lead 13 are configured to eliminate a shear force applied on the lower surface 131 of the lead 13. The recessed portion 133 has a surface recessed with respect to the lower surface 131 of the lead 13. Thus, once the force applied and transmitted on the lower surface 131 of the lead 13 meets the recessed portion 133, the shear stress is eliminated. That is, the recessed portion 133 is a barricade to block a transmission of the shear stress on the lower surface 131 of the lead 13. Further, since the recessed portions 133 are mis-aligned with each other on the lower surface 131, the shear force applied on the lower surface 131 meets the recessed portion 133 and is blocked and eliminated by the recessed portion 133 whether the transmission of the shear stress is in the X-direction, in the Y-direction or in any other direction. That is, no matter which direction the shear stress comes from on the lower surface 133 of the lead 13, the shear stress is eliminated by the recessed portion 133. Given the above, no shear stress passes across the whole lower surface 131 of the lead 13.

FIG. 1C illustrates an enlarged view of portion B in FIG. 1A. That is, the lower surface 131 of the lead 13 is shown in FIG. 1C. Referring to FIG. 1C, a plurality of the recessed portions 133 are formed on the lower surface 131 of the lead 13. The recessed portion 133 may be adjacent to the first side 135 or the second side 137 of the lower surface 131 of the lead 13 but spaced apart from the first side 135 or the second side 137 of the lower surface 131 of the lead 13. In some embodiments of the present disclosure, the recessed portion 133 is surrounded by the lower surface 131 of the lead 13. The recessed portions 133 are mis-aligned with each other. In some embodiments of the present disclosure, the recessed portion 133 includes a first recessed portion 1331 and a second recessed portion 1332. As shown in FIG. 1C, the first recessed portion 1331 and the second recessed portion 1332 may be arranged to be adjacent to each other and be spaced apart from each other. Further, the first recessed portion 1331 and the second recessed portion 1332 may be mis-aligned with each other. Thus, the first recessed portion 1331 and the second recessed portion 1332 may at least partially overlaps each other when viewed from an X-direction or when viewed from a Y-direction or when viewed form another direction.

As above mentioned, the recessed portions 133 are configured to eliminate a shear force applied on the lower surface 131 of the lead 13. The recessed portion 133 may block the transmission of the shear stress on the lower surface 131 of the lead 13. Referring to FIG. 1C, when a shear stress F4 is applied on the lower surface 131 and transmitted along the X-direction, the shear stress F3 meets at least one recessed portion 133 and thus the shear stress F3 is blocked and eliminated by the recessed portion(s) 133. When a shear stress F5 is applied on the lower surface 131 and transmitted along the Y-direction, the shear stress F5 meets at least one recessed portion 133 and thus the shear stress F5 is blocked and eliminated by the recessed portion(s) 133. A shear stress F6 is applied on the lower surface 131 and transmitted along a direction, which is not the X-direction or the Y-direction, the shear stress F6 meets at least one recessed portion 133 and thus the shear stress F6 is blocked and eliminated by the recessed portion(s) 133. In some embodiments of the present disclosure, a shear force strength of the recessed portion 1331 is different from a shear force strength of the recessed portion 1332. Moreover, the different sizes of the recessed portions 133 are configured to reduce or release the different shear stress at different position.

FIG. 1D illustrates another enlarged view of portion Ain FIG. 1A. As above mentioned, the recessed portions 113 may be mis-aligned with each other. In some embodiments of the present disclosure, a projection of the recessed portion 1131 onto a plane P1 overlaps with a projection of the recessed portion 1132 onto the plane P1 in a view from a perspective along an axis X1 extending on the surface 111 and normal to the plane P1.

FIG. 1E illustrates another enlarged view of portion B in FIG. 1A. As above mentioned, the recessed portions 133 may be mis-aligned with each other. In some embodiments of the present disclosure, a projection of the recessed portion 1331 onto a plane P2 overlaps with a projection of the recessed portion 1332 onto the plane P2 in a view from a perspective along an axis X2 extending on the surface 131 and normal to the plane P2.

As shown in FIG. 2A, the die paddle 11 includes an upper surface 112. The upper surface 112 of the die paddle 11 has a mounting area 1120 and a plurality of recessed portions 114. The mounting area 1120 is an area that an electronic component is mounted or disposed thereon. The mounting area 1120 may be substantially flat, and thus there is no recessed portion 114 is formed within the mounting area 120. In some embodiments of the recessed portion 114 are formed on the upper surface 112 of the die paddle 11 by a half-etching process. In some embodiments of the present disclosure, the recessed portions 114 include dimples. In some embodiments of the present disclosure, the recessed portions 114 are the same size. In some embodiments of the present disclosure, the sizes of the recessed portions 114 are not the same. Referring to FIG. 2A, the recessed portions 114 may be arranged to be spaced apart from each other and to be adjacent to each other. Further, the recessed portions 114 may be mis-aligned with each other on the upper surface 112 of the paddle portion 11. That is, the recessed portions 114 may at least partially overlaps each other when viewed from an X-direction on the upper surface 112, from a Y-direction on the upper surface 112 or from any other direction on the upper surface 112. The upper surface 112 of the die paddle 11 has a first side 116 and a second side 118 connected to the first side 116. A distance between the recessed portion 114 and the first side 116 of the upper surface 112 of the die paddle 11 is greater than zero, and a distance between the recessed portion 113 and the second side 118 of the upper surface 112 of the die paddle 11 is greater than zero. That is, the recessed portion 114 is spaced apart from the first side 116 and the second side 118 of the upper surface 112 of the die paddle 11.

The recessed portions 114 of the upper surface 112 of the die paddle 11 are configured to eliminate a shear force applied on the upper surface 112 of the die paddle 11. The recessed portion 114 has a surface recessed with respect to the upper surface 112 of the die paddle 11. Thus, once the shear force applied and transmitted on the upper surface 112 of the die paddle 11 meets the recessed portion 114, the shear stress is eliminated. That is, the recessed portion 114 is a barricade to block a transmission of the shear stress on the upper surface 112 of the die paddle 11. Further, since the recessed portions 114 are mis-aligned with each other on the upper surface 112, the shear force applied on the upper surface 112 meets the recessed portion 114 and is blocked and eliminated by the recessed portion 114 whether the transmission of the shear stress is in the X-direction, in the Y-direction or in any other direction. That is, no matter which direction the shear stress comes from on the upper surface 112 of the die paddle 11, the shear stress is eliminated by the recessed portion 114. Given the above, no shear stress passes across the whole upper surface 112 of the paddle portion 11.

FIG. 2B illustrates an enlarged view of portion C in FIG. 2A. That is, a portion of the upper surface 112 of the die paddle 11 is shown in FIG. 2B. Referring to FIG. 2B, the upper surface 112 of the die paddle 11 has a mounting area 1120. A plurality of the recessed portions 114 are formed on the upper surface 111 of the die paddle 11, but there is no recessed portion 114 formed within the mounting area 1120. The recessed portion 114 may be adjacent to the first side 116 or the second side 118 of the upper surface 112 of the die paddle 11 but spaced apart from the first side 116 or the second side 118 of the upper surface 112 of the die paddle 11. In some embodiments of the present disclosure, the recessed portion 114 is surrounded by the upper surface 112 of the die paddle 11. The recessed portions 114 are mis-aligned with each other. In some embodiments of the present disclosure, the recessed portion 114 includes a first recessed portion 1141 and a second recessed portion 1142. As shown in FIG. 2B, the first recessed portion 1141 and the second recessed portion 1142 may be arranged to be adjacent to each other and be spaced apart from each other. Further, the first recessed portion 1141 and the second recessed portion 1142 may be mis-aligned with each other. Thus, the first recessed portion 1141 and the second recessed portion 1142 may at least partially overlaps each other when viewed from an X-direction or when viewed from a Y-direction or when viewed form another direction.

As above mentioned, the recessed portions 114 are configured to eliminate a shear force applied on the upper surface 112 of the die paddle 11. The recessed portion 114 may block the transmission of the shear stress on the upper surface 112 of the die paddle 11. Referring to FIG. 2B, when a shear stress F7 is applied on the upper surface 111 and transmitted along the X-direction, the shear stress F7 meets at least one recessed portion 114 and thus the shear stress F7 is blocked and eliminated by the recessed portion(s) 114. When a shear stress F8 is applied on the upper surface 112 and transmitted along the Y-direction, the shear stress F8 meets at least one recessed portion 114 and thus the shear stress F8 is blocked and eliminated by the recessed portion(s) 114 A shear stress F9 is applied on the lower surface 111 and transmitted along a direction, which is not the X-direction or the Y-direction, the shear stress F9 meets at least one recessed portion 114 and thus the shear stress F9 is blocked and eliminated by the recessed portion(s) 114. In some embodiments of the present disclosure, a shear force strength of the recessed portion 1141 is different from a shear force strength of the recessed portion 1142. Moreover, the different sizes of the recessed portions 114 are configured to reduce or release the different shear stress at different position.

As shown in FIG. 2A, the lead 13 includes an upper surface 132. Further, the upper surface 132 of the lead 13 has a bounding area 1320 and a plurality of recessed portions 134. The bonding area 1320 is configured to electrically connect an electrical connection, such as a bonding wire. The bonding area 130 may be substantially flat and thus there is no recessed portion 134 is formed within the bonding area 1320. In some embodiments of the recessed portion 133 are formed on the upper surface 132 of the lead 13 by a half-etching process. In some embodiments of the present disclosure, the recessed portions 134 include dimples. In some embodiments of the present disclosure, the recessed portions 134 are the same size. In some embodiments of the present disclosure, the sizes of the recessed portions 134 are not the same. Referring to FIG. 2A, the recessed portions 134 may be arranged to be spaced apart from each other and to be adjacent to each other. Further, the recessed portions 134 may be mis-aligned with each other on the upper surface 132 of the lead 13. That is, the recessed portions 134 may at least partially overlaps each other when viewed from an X-direction on the upper surface 132, from a Y-direction on the upper surface 133 or from any other direction on the upper surface 132. The upper 132 of the lead 13 has a side 136. A distance between the recessed portion 134 and the first side 136 of the lead 13 is greater than zero. That is, the recessed portion 134 is spaced apart from the side 136 of the upper surface 132 of the lead 13.

The recessed portions 134 of the upper surface 132 of the lead 13 are configured to eliminate a shear force applied on the upper surface 132 of the lead 13. The recessed portion 134 has a surface recessed with respect to the upper surface 132 of the lead 13. Thus, once the shear force applied and transmitted on the upper surface 132 of the lead 13 meets the recessed portion 132, the shear stress is eliminated. That is, the recessed portion 134 is a barricade to block a transmission of the shear stress on the upper surface 132 of the lead 13. Further, since the recessed portions 134 are mis-aligned with each other on the upper surface 132, the shear force applied on the upper surface 132 meets the recessed portion 134 and is blocked and eliminated by the recessed portion 134 whether the transmission of the shear stress is in the X-direction, in the Y-direction or in any other direction. That is, no matter which direction the shear stress comes from on the upper surface 132 of the lead 13, the shear stress is eliminated by the recessed portion 134. Given the above, no shear stress passes across the whole upper surface 132 of the lead 13.

FIG. 2C illustrates an enlarged view of portion D in FIG. 2A. That is, the upper surface 132 of the lead 13 is shown in FIG. 2C. Referring to FIG. 2C, a plurality of the recessed portions 134 are formed on the upper surface 132 of the lead 13, but there is no recessed portions 134 formed within the bonding area 1320. The recessed portion 134 may be adjacent to the side 136 of the upper surface 132 of the lead 13 but spaced apart from the side 136 of the upper surface 132 of the lead 13. In some embodiments of the present disclosure, the recessed portion 134 is surrounded by the upper surface 132 of the lead 13. The recessed portions 134 are mis-aligned with each other. In some embodiments of the present disclosure, the recessed portion 134 includes a first recessed portion 1341 and a second recessed portion 1342. As shown in FIG. 2C, the first recessed portion 1341 and the second recessed portion 1342 may be arranged to be adjacent to each other and be spaced apart from each other. Further, the first recessed portion 1341 and the second recessed portion 1342 may be mis-aligned with each other. Thus, the first recessed portion 1341 and the second recessed portion 1342 may at least partially overlaps each other when viewed from an X-direction or when viewed from a Y-direction or when viewed form another direction.

As above mentioned, the recessed portions 134 are configured to eliminate a shear force applied on the upper surface 132 of the lead 13. The recessed portion 134 may block the transmission of the shear stress on the upper surface 132 of the lead 13. Referring to FIG. 2C, when a shear stress F10 is applied on the upper surface 131 and transmitted along the X-direction, the shear stress F10 meets at least one recessed portion 134 and thus the shear stress F10 is blocked and eliminated by the recessed portion(s) 134. When a shear stress F11 is applied on the upper surface 132 and transmitted along the Y-direction, the shear stress F12 meets at least one recessed portion 134 and thus the shear stress F11 is blocked and eliminated by the recessed portion(s) 134. A shear stress F11 is applied on the upper surface 132 and transmitted along a direction, which is not the X-direction or the Y-direction, the shear stress F12 meets at least one recessed portion 134 and thus the shear stress F12 is blocked and eliminated by the recessed portion(s) 134. In some embodiments of the present disclosure, a shear force strength of the recessed portion 1341 is different from a shear force strength of the recessed portion 1342. Moreover, the different sizes of the recessed portions 134 are configured to reduce or release the different shear stress at different position.

FIG. 2D illustrates another enlarged view of portion C in FIG. 2A. As above mentioned, the recessed portions 114 may be mis-aligned with each other. In some embodiments of the present disclosure, a projection of the recessed portion 1141 onto a plane P3 overlaps with a projection of the recessed portion 1142 onto the plane P3 in a view from a perspective along an axis X3 extending on the surface 112 and normal to the plane P1.

FIG. 2E illustrates another enlarged view of portion D in FIG. 2A. As above mentioned, the recessed portions 134 may be mis-aligned with each other. In some embodiments of the present disclosure, a projection of the recessed portion 1341 onto a plane P4 overlaps with a projection of the recessed portion 1342 onto the plane P4 in a view from a perspective along an axis X4 extending on the surface 132 and normal to the plane P4.

FIG. 2F illustrates a schematic cross-sectional view along line I-I′ in FIG. 2A. As shown in FIG. 2C, the lead frame 1 includes the die paddle 11 and the leads 13 spaced apart from the die paddle 11.

Referring to FIG. 2F, the die paddle 11 has the upper surface 112 and the lower surface 111 opposite to the upper surface 112. The lower surface 111 of the die paddle 11 has the recessed portions 113. Each of the recessed portions 113 has a surface 1130 recessed with respect to the lower surface 111 of the die paddle 11. Further, the upper surface 112 of the die paddle 11 has a mounting area 1120 and recessed portions 112. As shown in FIG. 2D, there is no recessed portion 112 formed within the mounting area 1120. Each of the recessed portions 112 has a surface 1120 recessed with respect to the upper surface 112 of the die paddle 11.

Referring to FIG. 2F, the lead 13 has the upper surface 132 and the lower surface 131 opposite to the upper surface 132. The lower surface 131 of the lead 13 has the recessed portions 133. Each of the recessed portions 133 has a surface 1330 recessed with respect to the lower surface 131 of the lead 13. Further, the upper surface 132 of the lead 13 has a bonding area 1320 and recessed portions 132. As shown in FIG. 2F, there is no recessed portion 132 formed within the bonding area 1320. Each of the recessed portions 132 has a surface 1320 recessed with respect to the upper surface 132 of the lead 13.

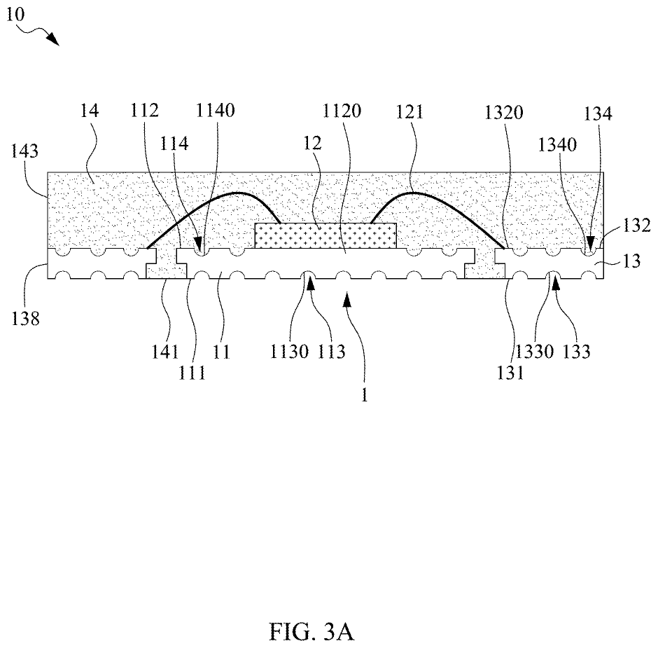

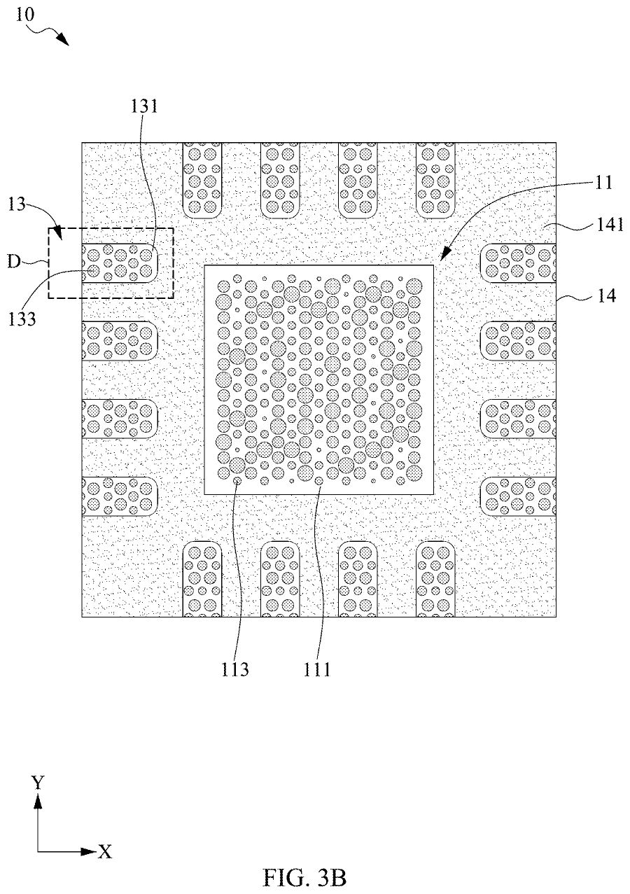

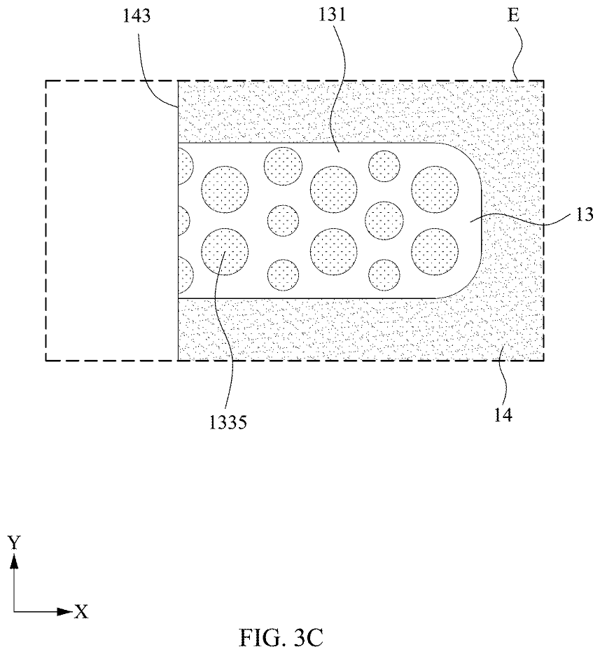

FIG. 3A is a schematic cross-sectional view of a package structure 10 in accordance with an embodiment of the instant disclosure. The package structure 10 includes the lead frame 10, an electronic component 12 and a package body 14.

Referring to FIG. 3A, the electronic component 12 is disposed or mounted on the upper surface 112 of the die paddle 11 of the lead frame. The electronic component 12 is disposed within the mounting area 1120. Further, at least one electrical connection 121 electrically connects the electronic component 12 and the lead 13 of the lead frame 1. In some embodiments of the present disclosure, the electrical connection 121 includes a bonding wire. One end of the electrical connection 121 is disposed on the bonding area 1320 of the upper surface 132 of the lead 13.

The package body 14 is disposed on the upper surface 112 of the paddle portion 11 and the upper surfaces 132 of the leads 13 and encapsulated the electronic component 12 and the lead frame 1. As shown in FIG. 3A, the package body 14 may extend into the recessed portions 114 of the upper surface 112 of the die paddle 11 and abut the surfaces 1140 of the recessed portions 114. As above mentioned, the recessed portions 114 of the upper surface 112 of the die paddle 11 are configured to eliminate the shear force applied on the upper surface 112 of the die paddle 11. Thus, when performing a stress test, a shear stress generated by the stress test is eliminated by the recessed portions 114 and the shear stress cannot across the upper surface 112 of the die paddle 11. Therefore, a crack issue between the package body 14 and the upper surface 112 of the die paddle 11 may be eliminated. In some embodiments of the present disclosure, the stress test comprises a drop test. Given the above, the recessed portions 114 of the upper surface 112 of the die paddle 11 are configured to hold the package body 14. That is, there is a mold lock between the package body 14 and the recessed portions 114 of the upper surface 112 of the die paddle 11, and thus the package body 14 is firmly disposed on the upper surface 112 of the die paddle 11.

Moreover, the package body 14 may extend into the recessed portions 134 of the upper surface 132 of the lead 13 and abut the surfaces 1340 of the recessed portions 134. As above mentioned, the recessed portions 134 of the upper surface 132 of the lead 13 are configured to eliminate the shear force applied on the upper surface 132 of the lead 13. Thus, when performing a stress test, a shear stress generated by the stress test is eliminated by the recessed portions 134 and the shear stress cannot across the upper surface 132 of the lead 13. Therefore, a crack issue between the package body 14 and the upper surface 132 of the lead 13 may be eliminated. In some embodiments of the present disclosure, the stress test comprises a drop test. Given the above, the recessed portions 134 of the upper surface 132 of the lead 13 are configured to hold the package body 14. That is, there is a mold lock between the package body 14 and the recessed portions 134 of the upper surface 132 of the lead 13, and thus the package body 14 is firmly disposed on the upper surface 132 of the die paddle 13.

As shown in FIG. 3A, the lower surface 111 of the die paddle 11 and the lower surfaces of the leads 13 are not covered by the package body 14. Thus, the lower surface 111 of the die paddle 11 and the lower surfaces of the leads 13 are exposed from a lower surface 141 of the package body 13. Accordingly, the recessed portions 113 of the lower surface 111 of the die paddle 11 and the surface 1130 thereof and the recessed portions 133 of the lower surface 131 of the leads 13 and the surface 1330 thereof are exposed from the lower surface 141 of the package body as well.

In addition, the lead frame 1 includes a side surface 138 at the lead 13. The side surface 138 may be substantially coplanar with a side surface 143 of the package body 14.

FIG. 3B is a schematic bottom view of a package structure 10 in accordance with an embodiment of the instant disclosure. Referring to FIG. 3B, the lower surface 111 of the die paddle 11 and the lower surfaces 131 of the leads 13 are not covered by the package body 14 and thus are exposed from the lower surface 141 of the package body. Accordingly, the recessed portions 113 of the lower surface 111 of the die paddle 11 and the recessed portions 133 of the lower surfaces 131 of the leads 13 are exposed from the lower surface 141 of the package body 14 as well.

FIG. 3C illustrates an enlarged view of portion E in FIG. 3B. Referring to FIG. 3C, the lower surface 131 of the lead 13 may include a recessed portion 1335 which is adjacent to an outer side of the package structure 10. In some embodiments of the present disclosure, a horizontal distance between the recessed portion 1335 and the side 143 of the package body 14 is equal to or greater than zero. Similarly, the upper surface 132 of the lead 13 may include a recessed portion 134 which is adjacent to an outer side of the package structure 10, and a horizontal distance between such recessed portion 134 and the side 143 of the package body 14 is equal to or greater than zero.

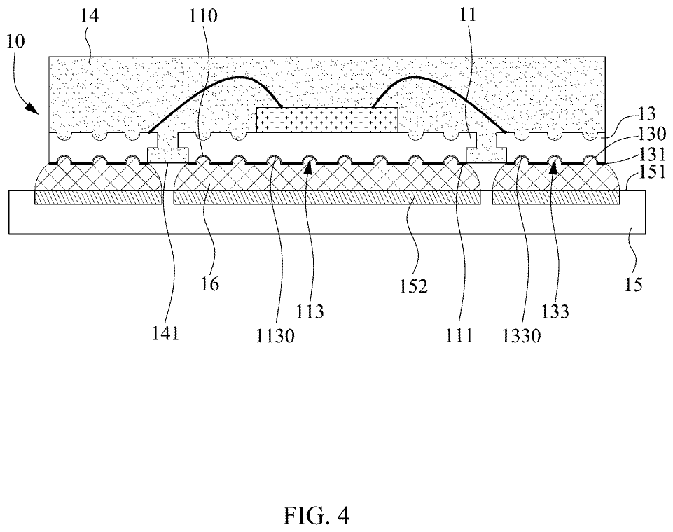

FIG. 4 is a schematic cross-sectional view of an electronic device 100 in accordance with an embodiment of the instant disclosure. The electronic device 100 includes the package structure 10 mounted or disposed on a carrier 15 through electrical connections 16.

Referring to FIG. 4, the package structure 10 is mounted or disposed on an upper surface 151 of the carrier 15, and a plurality of electrical connections 16 are disposed between the package structure 10 and the carrier 15. The lower surface 111 of the die paddle 11 and the lower surfaces 131 of the leads 13 are exposed from the lower surface 141 of the package body 14. The electrical connections 16 are disposed or mounted on the lower surface 111 of the die paddle 11 and the lower surfaces 131 of the leads 13. In some embodiments of the present disclosure, the electrical connection 16 includes solder material. The electrical connection 16 may include a solder ball. As shown in FIG. 4, the electrical connection 16 may extend into the recessed portions 113 of the lower surface 111 of the die paddle 11 and abut the surfaces 1130 of the recessed portions 113 of the lower surface 111 of the die paddle 11. As above mentioned, the recessed portions 113 of the lower surface 111 of the die paddle 11 are configured to eliminate the shear force applied on the lower surface 111 of the die paddle 11. Thus, when performing a stress test, a shear stress generated by the stress test is eliminated by the recessed portions 113 and the shear stress cannot across the lower surface 111 of the die paddle 11. Therefore, a crack issue between the electrical connection 16 and the lower surface 111 of the die paddle 11 may be eliminated. In some embodiments of the present disclosure, the stress test comprises a drop test. Given the above, the recessed portions 113 of the lower surface 111 of the die paddle 11 are configured to hold the electrical connection 16. That is, there is a solder lock between the electrical connection 16 and the recessed portions 113 of the lower surface 111 of the die paddle 11, and thus the electrical connection 16 is firmly disposed on the lower surface 111 of the die paddle 11. In addition, an IMC (intermetallic compound) structure 110 may be continuously formed between the lower surface 111 of the die paddle 11 and the electrical connection 16 and between the surface 1130 of the recessed portion 113 and the electrical connection 16.

Referring to FIG. 4, the electrical connection 16 may extend into the recessed portions 133 of the lower surface 131 of the lead 13 and abut the surfaces 1330 of the recessed portions 133 of the lower surface 131 of the lead 13. As above mentioned, the recessed portions 133 of the lower surface 131 of the lead 13 are configured to eliminate the shear force applied on the lower surface 131 of the lead 13. Thus, when performing a stress test, a shear stress generated by the stress test is eliminated by the recessed portions 133 and the shear stress cannot across the lower surface 131 of the lead 11. Therefore, a crack issue between the electrical connection 16 and the lower surface 131 of the lead 13 may be eliminated. In some embodiments of the present disclosure, the stress test comprises a drop test. Given the above, the recessed portions 133 of the lower surface 131 of the lead 13 are configured to hold the electrical connection 16. That is, there is a solder lock between the electrical connection 16 and the recessed portions 133 of the lower surface 131 of the lead 13, and thus the electrical connection 16 is firmly disposed on the lower surface 131 of the lead 13. In addition, an IMC (intermetallic compound) structure 130 may be continuously formed between the lower surface 131 of the lead 13 and the electrical connection 16 and between the surface 1330 of the recessed portion 133 and the electrical connection 16.

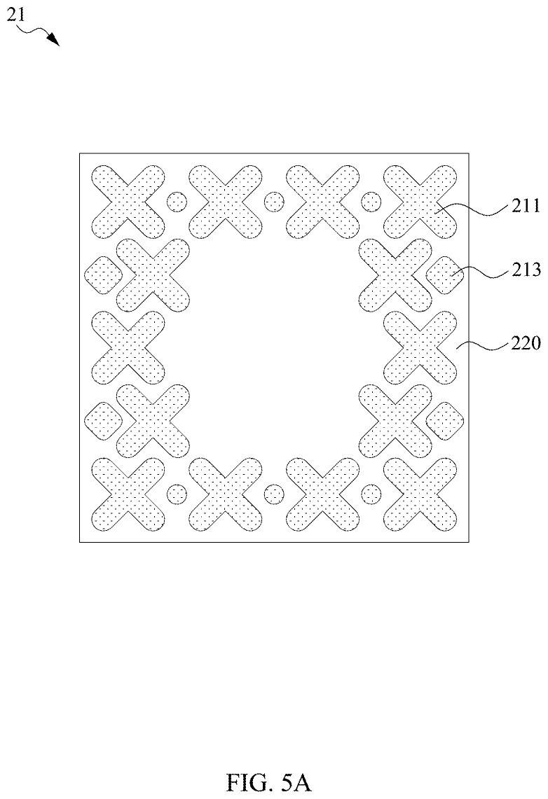

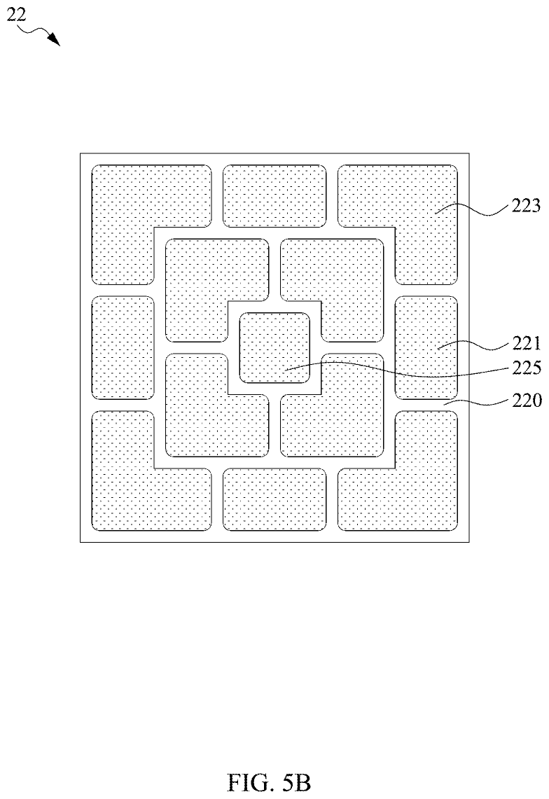

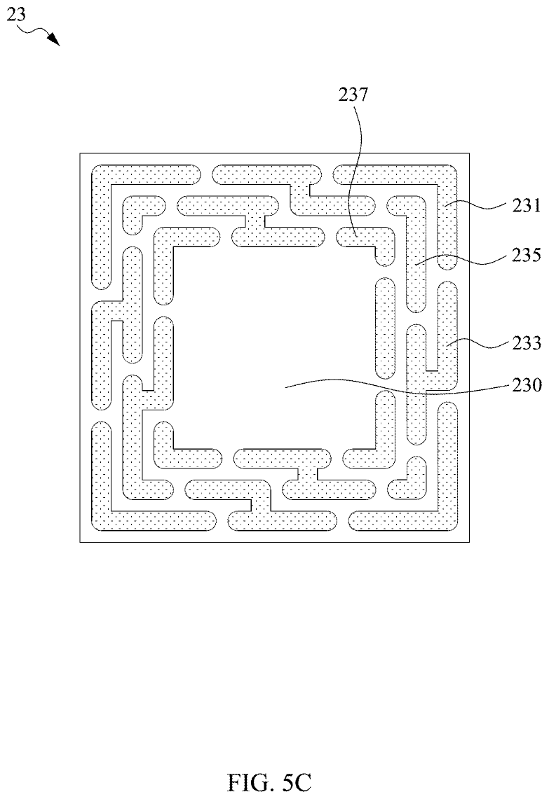

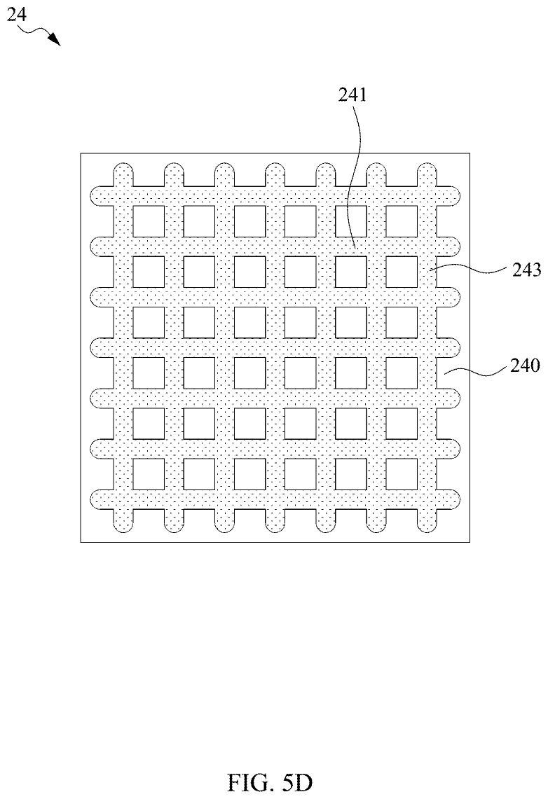

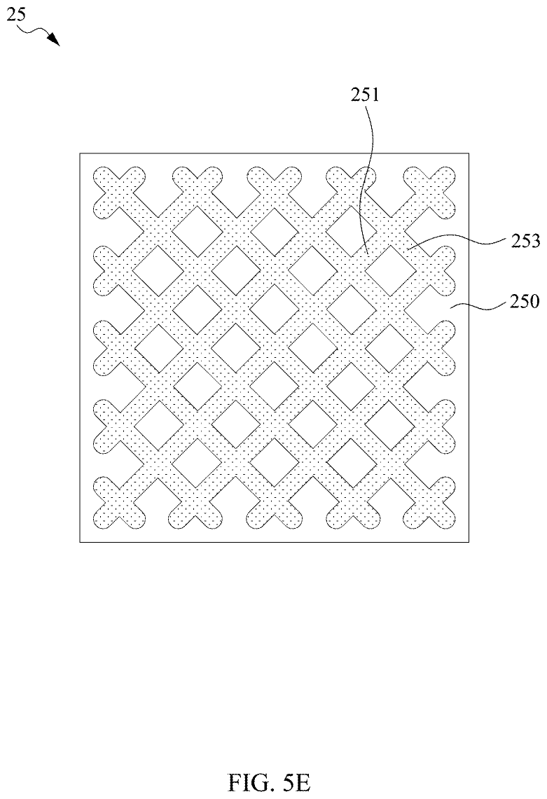

FIG. 5A is a schematic view of a die paddle 21 of a lead frame in accordance with an embodiment of the instant disclosure. As shown in FIG. 5A, a plurality of recessed portions 211 and 213 are formed on a surface 210 of the die paddle 21. In some embodiments of the present disclosure, shapes and sizes of the recessed portions 211 and 213 are not the same.

FIG. 5B is a schematic view of a die paddle 22 of a lead frame in accordance with an embodiment of the instant disclosure. As shown in FIG. 5B, a plurality of recessed portions 221, 223 and 225 are formed on a surface 220 of the die paddle 22. In some embodiments of the present disclosure, shapes and sizes of the recessed portions 221, 223 and 225 are not the same.

FIG. 5C is a schematic view of a die paddle 23 of a lead frame in accordance with an embodiment of the instant disclosure. As shown in FIG. 5C, a plurality of recessed portions 231, 233 and 235 are formed on a surface 230 of the die paddle 23. In some embodiments of the present disclosure, shapes and sizes of the recessed portions 231, 233 and 235 are not the same.

FIG. 5D is a schematic view of a die paddle 24 of a lead frame in accordance with an embodiment of the instant disclosure. As shown in FIG. 5D, a plurality of recessed portions 241 and 243 are formed on a surface 240 of the die paddle 24. In some embodiments of the present disclosure, the recessed portions 241 and 243 are interlaced with each other.

FIG. 5E is a schematic view of a die paddle 25 of a lead frame in accordance with an embodiment of the instant disclosure. As shown in FIG. 5E, a plurality of recessed portions 251 and 253 are formed on a surface 250 of the die paddle 25. In some embodiments of the present disclosure, the recessed portions 251 and 253 are interlaced with each other.

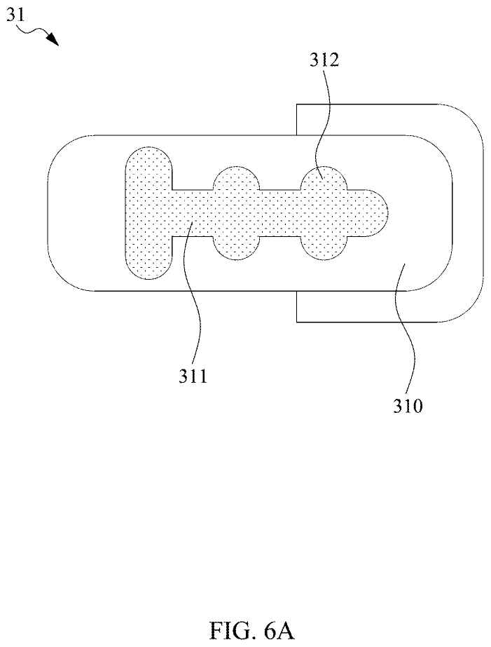

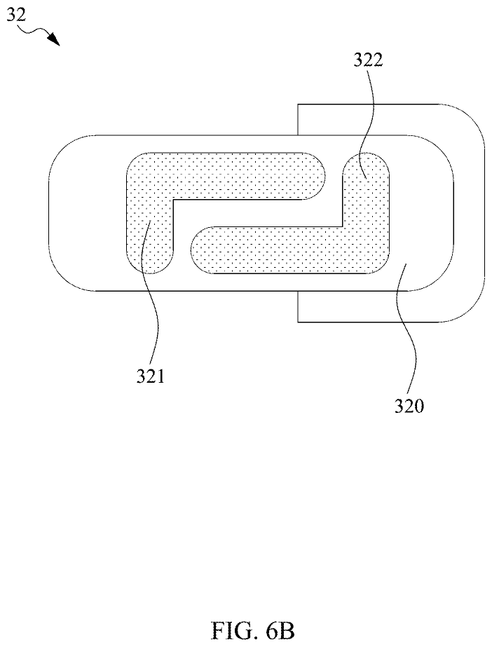

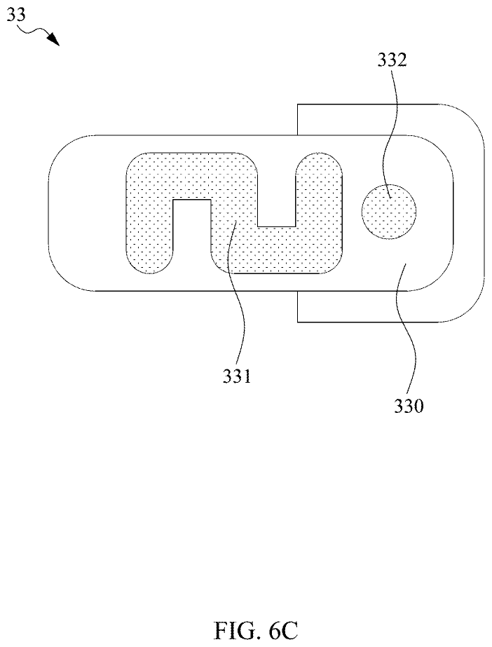

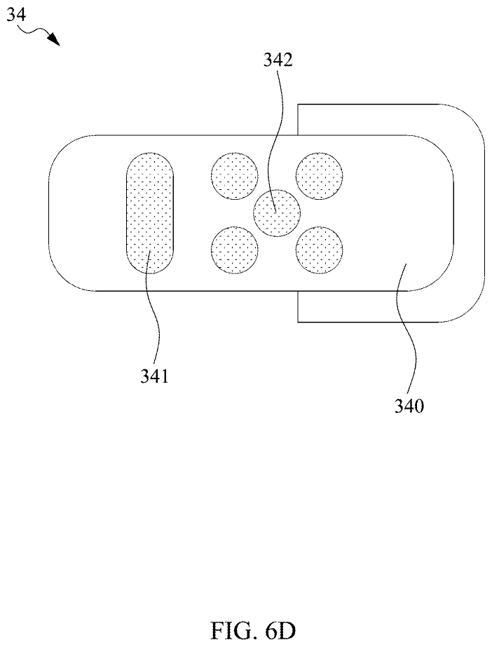

FIG. 6A is a schematic view of a lead 31 of a lead frame in accordance with an embodiment of the instant disclosure. As shown in FIG. 6A, a plurality of recessed portions 311 and 312 are formed on a surface 310 of the lead 31. In some embodiments of the present disclosure, the recessed portions 311 and 312 are interlaced with each other.

FIG. 6B is a schematic view of a lead 32 of a lead frame in accordance with an embodiment of the instant disclosure. As shown in FIG. 6B, a plurality of recessed portions 321 and 322 are formed on a surface 320 of the lead 32.

FIG. 6C is a schematic view of a lead 33 of a lead frame in accordance with an embodiment of the instant disclosure. As shown in FIG. 6C, a plurality of recessed portions 331 and 332 are formed on a surface 330 of the lead 33. In some embodiments of the present disclosure, shapes and sizes of the recessed portions 331 and 332 are not the same.

FIG. 6D is a schematic view of a lead 34 of a lead frame in accordance with an embodiment of the instant disclosure. As shown in FIG. 6D, a plurality of recessed portions 341 and 342 are formed on a surface 340 of the lead 34. In some embodiments of the present disclosure, shapes and sizes of the recessed portions 341 and 342 are not the same.

As used herein, the singular terms “a,” “an,” and “the” may include a plurality of referents unless the context clearly dictates otherwise.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if the difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range were explicitly specified.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein are described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations on the present disclosure.

What is claimed is:

1. An electronic device comprising:
a circuit pattern layer, comprising:
a first surface;
a first dimple recessed with respect to the first surface; and
a second dimple recessed with respect to the first surface and adjacent to and spaced apart from the first dimple;
wherein a projection of the first dimple onto a plane overlaps with a projection of the second dimple onto the plane in a view from a perspective along a first axis extending on the first surface and normal to the plane.

2. The electronic device of claim 1, wherein the first dimple is surrounded by the first surface and the second dimple is surrounded by the first surface.

3. The electronic device of claim 1, wherein the circuit pattern layer has a second surface opposite to the first surface, a third dimple recessed with respect to the second surface and a fourth dimple recessed with respect to the second surface and adjacent to and spaced apart from the third dimple, and wherein a projection of the third dimple onto a plane overlaps with a projection of the fourth dimple onto the plane in a view from a perspective along a second axis extending on the second surface and normal to the plane.

4. The electronic device of claim 1, wherein the circuit pattern layer comprises a first region and a second region spaced apart from the first region, wherein the first surface, the first dimple and the second dimple are in the second region.

5. The electronic device of claim 4, wherein the first region is a die paddle and the second region is a lead, or vice versa.

6. The electronic device of claim 1, further comprising a package body disposed on the first surface of the circuit pattern layer and abutting the first dimple and the second dimple of the circuit pattern layer.

7. The electronic device of claim 1, further comprising an electrical connection disposed on the first surface of the circuit pattern layer and abutting the first dimple and the second dimple of the circuit pattern layer.

8. The electronic device of claim 7, further comprising an IMC (intermetallic compound) structure continuously formed between the electrical connection and the first surface of the circuit pattern layer and between the electrical connection and the first dimple of the circuit layer.

9. The electronic device of claim 4, further comprising an electronic component disposed on the first region and an electrical connection electrically connecting the electronic component and the second region, wherein an end of the electrical connection is disposed on an area of the second region and the area of the second region is free of any part shaped like the first dimple and the second dimple of the circuit pattern layer.

10. The electronic device of claim 5, further comprising an electronic component disposed on an area of the first region, wherein the area of the first region is free of any part shaped like the first dimple and the second dimple of the circuit pattern layer.

11. An electronic device, comprising:
a circuit pattern layer, comprising:
a first surface, and
a first structure formed on the first surface;
wherein the first structure is configured to reduce a transmission of a first shear force applied on the first surface of the circuit pattern layer.

12. The electronic device of claim 11, wherein the circuit pattern layer comprises a second structure formed on the first surface and spaced apart from the first structure, and wherein the second structure configured to reduce a transmission of a second shear force applied on the first surface of the circuit pattern layer.

13. The electronic device of claim 12, wherein a direction of the transmission of the first shear force is different from a direction of the transmission of the second shear force.

14. The electronic device of claim 11, wherein the circuit pattern layer has a second surface opposite to the first surface and a third structure formed on the second surface, and wherein the third structure is configured to reduce a transmission of a third shear force applied on the second surface of the circuit pattern layer.

15. The electronic device of claim 14, wherein a shear force strength of the first structure is different from a shear force strength of the third structure.

16. An electronic device, comprising:
a lead frame having a first surface with a plurality of recessed portions, and
a component attached to the first surface of the lead frame;
wherein the first surface and the recessed portions of the lead frame are configured to inhibit delamination between the component and the lead frame when undergoing a stress transmitted along the first surface and substantially parallel to the first surface.

17. The electronic device of claim 16, wherein the component comprises a package body or an electrical connection.

18. The electronic device of claim 17, further comprising an electronic component disposed on an area of the first surface of the lead frame and encapsulated by the package body, wherein the area of the first surface of the lead frame does not have any structure shaped like any of the recessed portion.

19. The electronic device of claim 16, wherein the recessed portions overlap with each other when viewed from any direction on the first surface and substantially parallel with the first surface.

20. The electronic device of claim 16, wherein sizes of the recessed portions are non-uniform.
